(19) United States
(12) Patent Application Publication
(10) Pub. No.: US 2024/0178143 A1
(43) Pub. Date: May 30, 2024

(54) BURIED OXIDE LAYER AND ETCH STOP LAYER PROCESS FOR DIRECT BACK SIDE CONTACT OF SEMICONDUCTOR DEVICE

(71) Applicant: INTERNATIONAL BUSINESS MACHINES CORPORATION, ARMONK, NY (US)

(72) Inventors: Tao Li, Slingerlands, NY (US); Ruilong Xie, Niskayuna, NY (US); Kisik Choi, Watervliet, NY (US); Nicholas Anthony Lanzillo, Wynantskill, NY (US)

(21) Appl. No.: 18/060,544

(22) Filed: Nov. 30, 2022

(51) Int. Cl. H01L 23/528; H01L 21/768; H01L 29/06; H01L 29/40; H01L 29/417; H01L 29/423; H01L 29/775

(52) U.S. Cl. CPC H01L 23/5286; H01L 21/768; H01L 29/0673; H01L 29/401; H01L 29/41725; H01L 29/42392; H01L 29/775

(57) ABSTRACT

A semiconductor chip device includes an electronic components layer supported by the substrate. The electronic components layer includes a plurality of active component structures. A power rail is positioned on a back side of the electronic components layer. A buried oxide layer is positioned between the electronic components layer and the power rail. A back side metal contact is buried in the buried oxide layer. The back side metal contact bridges one of the active components in the electronic components layer to the power rail.

### BACKGROUND

### Technical Field

The present disclosure generally relates to electrical devices, and more particularly, to a semiconductor device configured for back side contact through a buried oxide layer.

### Description of the Related Art

In semiconductor device manufacture, conventional methods use front side contact schemes. In front side contact schemes, some of the chip real estate is lost to providing power and signal connections to the processing components. There is a trend toward configuring devices for back side contact and power delivery. Back side power delivery frees up the front side of the device for more efficient use of the footprint for inclusion of electrical components that provide signal processing. Generally speaking, a back side connection to the electrical components on the front side of the device passes through a back side dielectric isolation layer.

### SUMMARY

According to an embodiment of the present disclosure, a semiconductor chip device is provided. The semiconductor device includes a substrate. An electronic components layer is supported by the substrate. The electronic components layer includes a plurality of active component structures. A power rail is positioned on a back side of the electronic components layer. A buried oxide layer is positioned between the electronic components layer and the power rail. A back side metal contact is buried in the buried oxide layer. The back side metal contact bridges one of the active components in the electronic components layer to the power rail.

According to another embodiment of the present disclosure, a semiconductor chip device is provided. The semiconductor device includes a substrate and a transistor supported by the substrate. The transistor includes a source and drain region, a gate region, and a semiconductor channel connected between the source and drain region. A buried oxide layer is positioned on a back side of the transistor. A buried metal contact is positioned in the buried oxide layer. The buried metal contact is in electrical contact with the source and drain region of the transistor. A power rail is positioned on a back side of the buried oxide layer and is in electrical contact with the buried metal contact.

According to another embodiment of the present disclosure, a method of manufacturing a semiconductor device is provided. The method includes forming a buried oxide layer on top of a substrate. A stack of nanosheets is formed on a front side of the buried oxide layer. The stack of nanosheets includes alternating layers of sacrificial layers and semiconductor channel layers. Active component support structures are patterned from the stack of nanosheets. A back side contact placeholder feature is formed buried in the buried oxide layer. On the front side of the buried oxide layer and on top of the back side contact placeholder feature, active components are formed using the active component support structures. The substrate is removed from a back side of the buried oxide layer. The back side contact placeholder feature is removed from the buried oxide layer. From the back side of the buried oxide layer, a metal contact is deposited in a cavity of the buried oxide layer, defined by the removal of the back side contact placeholder feature. A power rail is formed on the back side of the buried oxide layer, in contact with the metal contact.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1A is a legend showing axes of from a top view perspective of a logic region of a semiconductor device during a fabrication process shown in FIGS. 2-10D, consistent with embodiments of the present disclosure.

FIG. 1B is a legend showing axes of from a top view perspective of a passive device region of a semiconductor device during a fabrication process shown in FIGS. 2-10D, consistent with embodiments of the present disclosure

FIG. 2 is a cross-sectional view of a starting substrate formation for a semiconductor device, consistent with embodiments of the present disclosure.

FIG. 3 shows a view of recessing a top layer down, according to embodiments.

FIG. 4 shows a view of growing an epitaxial layer, according to an embodiment.

FIG. 5 shows a view of applying a condensation technique on the epitaxial layer of FIG. 4, according to an embodiment.

FIG. 6 shows a view of removing an oxidation layer, according to an embodiment.

FIGS. 7A-7D show views along perspectives of the logic and passive device regions of growing a nanosheet stack, according to an embodiment.

FIGS. 8A-8D show views of masking areas for removal of the nanosheet stack in the passive device region, according to an embodiment.

FIGS. 9A-9D show views of feature implantation in the passive device region, patterning of the stack of nanosheets at logic region, shallow trench isolation formation and hard mask removal, according to an embodiment.

FIGS. 10A-10D show views of forming dummy gate and spacers, sacrificial layers indentation and inner spacer formation according to an embodiment.

FIGS. 11A and 11B show views of the legends of FIGS. 1A and 1B, with an area of FIG. 11A highlighting a section of the logic region being worked on in FIGS. 12A-12D, according to an embodiment.

FIGS. 12A-12D show views of forming a sacrificial placeholder feature for the backside of the device, according to an embodiment.

FIGS. 13A and 13B show views of the legends of FIGS. 11A and 11B, showing the addition of a gate cut region in the logic region being worked on in FIGS. 14A-14D, according to an embodiment.

FIGS. 14A-14D show views forming logic and passive device features, according to an embodiment.

FIGS. 15A and 15B show views of the legends of FIGS. 13A and 13B, showing the addition of a metal contact regions, according to an embodiment.

FIGS. 16A-16D show views of forming a middle of line contact, back end of line interconnect structure, and bonding of a carrier wafer, according to an embodiment.

FIGS. 17A-17D show views of after flipping of the wafer, removing a substrate layer, according to an embodiment.

FIGS. 18A-18D show views after removing an etch stop layer, according to an embodiment.

FIGS. 19A-19D show views for removing a remaining substrate layer from the logic region, according to an embodiment.

FIGS. 20A-20D show views depositing an interlayer dielectric on the backside of the logic region, according to an embodiment.

FIGS. 21A-21D show views of backside power rail patterning in the logic device region, according to an embodiment.

FIGS. 22A-22D show views removing the sacrificial placeholder feature, consistent with embodiments of the present disclosure.

FIGS. 23A-23D show views of forming metallization contacts on the backside of the logic region, according to an embodiment.

FIGS. 24A-24D show views of forming an interconnect layer on the backside of the semiconductor device, according to an embodiment.

### DETAILED DESCRIPTION

### Overview

In conventional back side device contact fabrication, a bottom dielectric isolation (BDI) layer is positioned under the electrical components to prevent parasitic current leakage. While back side contact can provide many benefits to chip design, the manufacturing processes can be challenging because the eventual chip design involves planning the formation of features below the components level. Some techniques include flipping a wafer at a certain point to add features. However, while it may seem that simply flipping the wafer would allow one to process layers as it would when fabricating from the front side, there remain sensitive materials on the front side that can be easily damaged.

In making the connection to the power delivery source, sometimes a placeholder feature is formed that extends out from inside the level of the bottom dielectric isolation layer into a substrate (for example silicon). The placeholder is eventually replaced with a metal contact after flipping the wafer over and removing the silicon around the placeholder. Generally, damage to the placeholder material is not desired. Since the placeholder material can extend into the silicon region, preventing damage when removing the silicon is difficult. When the silicon is removed, the placeholder material and the bottom of the bottom dielectric layer are exposed. The thickness of the bottom dielectric is generally thin under the electrical component features. The process that removes the silicon can create microscopic channels into the BDI. During removal of the silicon substrate (and/or formation of other structures from the back side) chemicals can leech into the area where the processing electrical components are (for example, the source and drain epitaxial region) causing damage to material of the electrical components. In some devices, the gate material is not protected by the BDI. The gate material can be easily attacked by the chemistry used during the silicon substrate removal. As can be understood, the damage to the electrical components can lead to inefficiencies in the device and in some cases, defective devices.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Some embodiments use nanosheet structures. Nanosheets are typically able to maintain DC performance due to an adequate effective gate width, but AC performance is challenging because of the relatively large parasitic capacitance between the source/drain contact and gate. Cell height scaling difficulties are another issue, due to gate stack patterning challenges associated with tall nanosheet stacks. Tall nanosheet stacks are desirable, however, because they provide the same effective length at a smaller footprint, directly enabling area scaling.

In general, a buried oxide layer is formed on the back side of the electrical components layer to protect the electrical component features from damage during processes that form a back side connection to the electrical components. In some embodiments, the placeholder used to form an electrical contact from the back side may be buried entirely within the buried oxide layer so that the place holder material is not damaged when removing a surrounding substrate material.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Electrical components layer: Reference to an electrical components layer refers to a region of a semiconductor device that includes electrical features for computing and processing signals. The layer may include active and/or passive devices. The output from this layer may be provided to other parts of the overall device in some embodiments.

Active component: Reference to an active component or active component layer refers to electronic components that are parts of a circuit that rely on an external power source to control or modify electrical signals. Active components include for example, transistors, amplifiers, integrated circuits, diodes, photovoltaics, and rectifiers.

Passive component: Reference to a passive component refers to devices that are incapable of controlling current by means of another electrical signal. Examples of passive components include resistors, inductors, capacitors, transformers, diodes and sensors.

Back End of Line (BEOL): The back end of line is a layer of integrated circuit fabrication where the individual electronic components become interconnected with wiring on a wafer or other substrate. In embodiments below, the BEOL may be shown placed on the “front side” of a layer of electrical components.

Back Side Interconnect: A back side interconnect is a layer of connections connecting electrical components from the back side of their layer or support structure. In embodiments disclosed below, the back side interconnect may be on a side of the layer of electrical components opposite the BEOL.

Substrate: Reference to a substrate may refer to material that provides a support structure to features in or on top of the substrate material. As used below, there may be more than one substrate present in an embodiment shown. Also, since embodiments below are generally shown in cross-section, it should be understood that a substrate for a layer with patterned features may not be visible in the view so as to highlight the features for the layer.

Logic Device Region: Reference to a logic device region generally refers to an area of the semiconductor device that includes active components for processing signals and computation. The logic device region may include and integrated circuit of active components or individual active components. Circuits or components in the logic device region may include digital or analog units.

Passive Device Region: Reference to a passive device region refers to an area of the semiconductor device that includes passive electrical devices.

### Example Device Structure

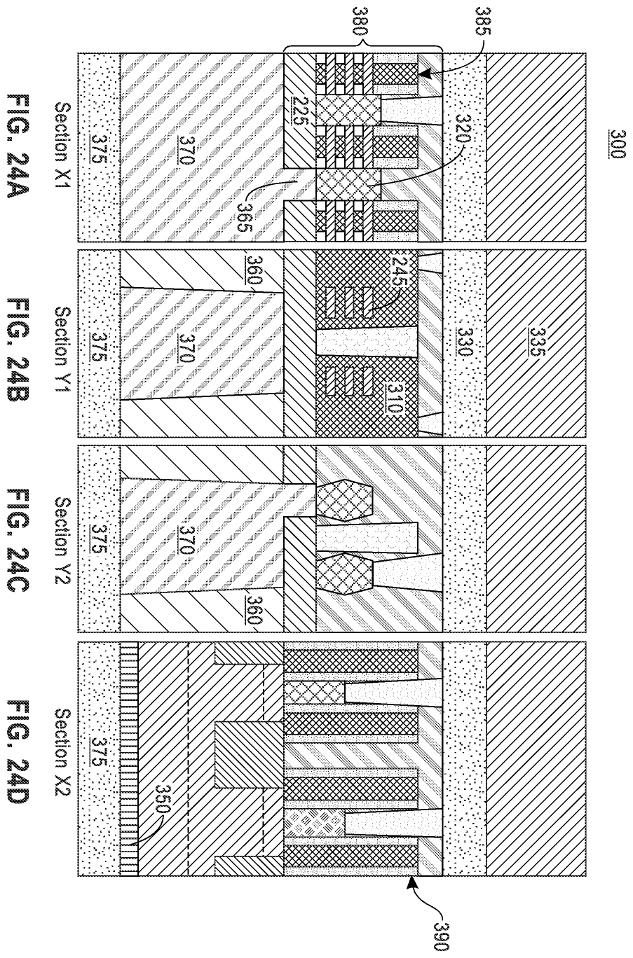

Referring temporarily now to FIGS. 24A-24D, a cross-sectional view of a semiconductor device 300 (referred to generally as the “device 300”) is shown, consistent with embodiments of the disclosure. As will be seen below, the embodiment shown in FIGS. 24A-24D is representative of a final result of a method of fabrication consistent with embodiments of the subject disclosure. The device 300 includes a buried oxide layer 225 positioned on a back side of an electrical components layer 380. The buried oxide layer 225 can be made of any suitable dielectric material, such as, for example, a silicon oxide. For sake of orientation, the device 300 is shown and will be described relative to the features in the electrical components layer 380. The top of the electrical components layer 380 may be considered the “front” side of the device. The bottom of the electrical components layer 380 may be considered the “back” side of the device. In some embodiments, the device 300 is configured for back side power delivery to the electrical components layer 380. Embodiments generally include a back side power contact. In the embodiment shown, one kind of back side power contact uses a power rail 370 coupled to the back side of the buried oxide layer 225. Some embodiments may include one or more metal contacts 365 buried in the buried oxide layer 225 that bridge power provided to the power rail 370 to one or more electrical components in the electrical components layer 380.

The electrical components layer 380 may include one or more active components 385.
The electrical components layer 380 may also include one or more passive components 390. The active component 385 may be for example a transistor. The transistor may be for example, a nanosheet field effect transistor (FET) that includes one or more stacks of semiconductor channels 245 connected to one or more source and drain regions 320. The power rail 370 may be connected to the source and drain region 320 (sometimes via the buried metal contact 365). In some embodiments, the transistor may include a gate all around (GAA) type of gate region 310.

Some embodiments are part of a larger semiconductor device architecture. For example, back side power delivery may be performed through a back side interconnect layer 375 coupled to the back side of the power rail 370. While not shown, a power source and other elements may be connected to or have means through the back side interconnect layer 375 to deliver signals to the electrical components layer 380. Some embodiments connect the front side of the electrical components layer 380 to a back end of line layer 330. Some embodiments may couple a carrier wafer 335 to the front side of the back end of line layer. What follows is a description for a method of manufacturing a representative semiconductor device 300 according to one or more embodiments.

In the description of the method for fabrication below, one or more substrates may be present at any one stage. Substrates can be the same material or different materials. Substrates can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

In some embodiments of the present disclosure, the buried oxide layer 225 acts as a substrate to support the electrical components layer 380 above it and to support the metal contact 365 inside the buried oxide layer 225. Some substrates are present during fabrication but are then lost from view as the device 300 evolves through the fabrication stages. Thus, while various perspective of the device 300 are shown below at different stages, it will be understood that while the supporting material of a substrate is lost from view, it may still be present in other perspectives of the device that are not the focus of the subject disclosure.

### Example Methodology of Manufacture

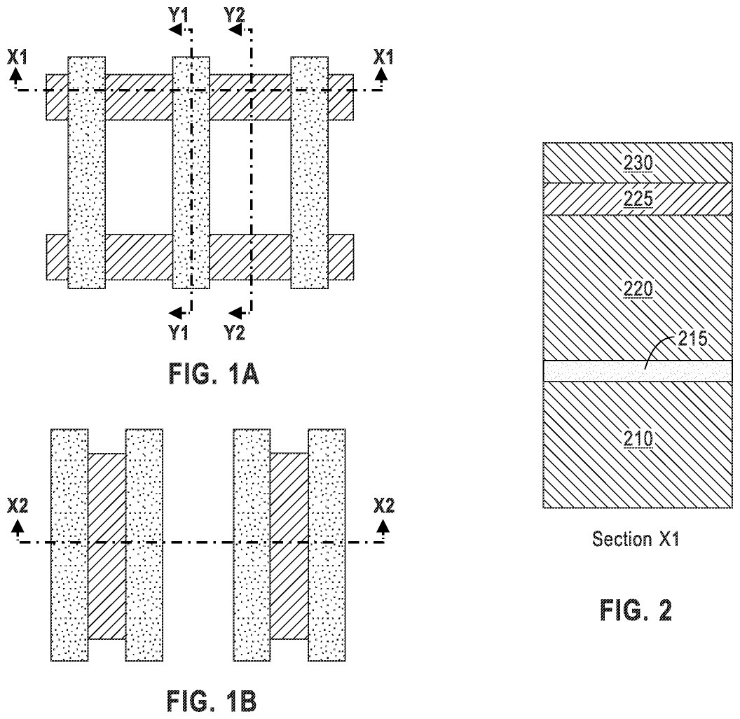

In the following, a process describes a general method of forming a semiconductor device 300 that has a buried oxide layer 225 protecting the electrical components during formation of a back side delivery structure. FIGS. 1A and 1B shows legends providing the various views of the semiconductor device during the fabrication process. In general, the legends show a top view of the device as the formation process evolves. FIG. 1A shows a cross-section of the logic device region of the device under formation. FIG. 1B shows a cross-section of the passive device region of the device under formation. In FIGS. 2-6, the device under formation is shown only from the perspective of the “X” axis since at the stages shown, the elements are mostly uniform in all directions and patterning has not begun. Thereafter, the process will show how actions affect different regions of the device under formation and various perspectives along their axis will be shown in juxtaposition for comparative reference of feature changes occurring in the device.

FIG. 2 shows an arbitrary starting substrate formation for a silicon on insulator wafer arrangement, while it will be understood that other substrates are supported by the teachings herein as well. The embodiment includes a first substrate layer 210, an etch stop layer 215 on top of the first substrate layer 210, a second substrate layer 220 on top of the etch stop layer 215, a dielectric layer 225 on top of the second substrate layer 220, and a third substrate layer 230 on top of the dielectric layer 225. The substrate layers 210, 220, and 230 may be any of the materials described above with respect to substrates. The dielectric layer 225 may be, for example, a thin layer of silicon dioxide (or other suitable dielectric material) and as the method progresses, will be referred to as the “buried oxide layer 225” or the “BOX layer 225”. The dielectric layer 225 may be, for example, approximately 30 nm-60 nm in thickness. The etch stop layer 215 may be, for example, silicon geranium or other suitable etch stop material.

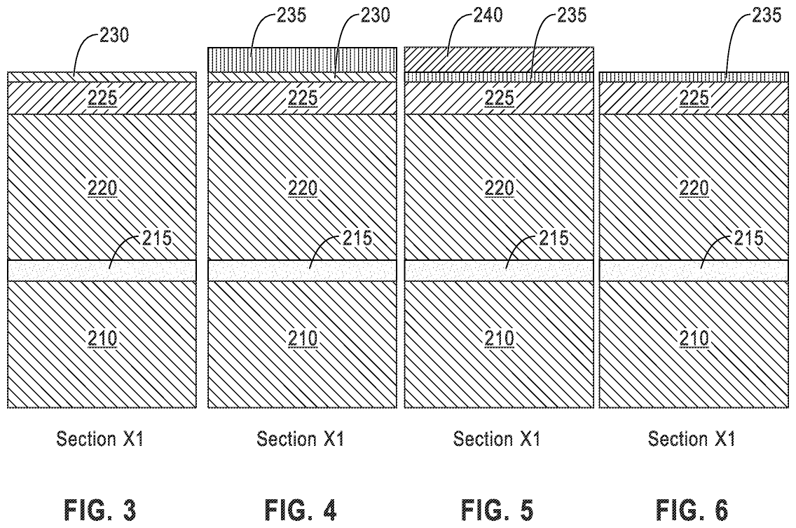

FIG. 3 shows the formation of FIG. 2 after a process of recessing down the third substrate layer 230. FIG. 4 shows the formation of FIG. 3 after growing an epitaxial layer 235 on top of the third substrate layer 230. The epitaxial layer 235 may be silicon geranium or other suitable epi growth material. FIG. 5 shows the result of a condensation process applied to the epitaxial layer 235 that provides a dielectric layer 240 on the top surface of the formation. FIG. 6 shows removal of the dielectric layer 240 (from condensation) exposing the underlying epitaxial layer 235. The epitaxial layer 235 will be used as a seed layer to on to which nanosheets will be formed in the next figures. The epitaxial layer 235 will be used as the first of multiple layers of sacrificial layers that will be removed and replaced with a high K metal gate further down the process. Accordingly, from here on out, reference to the layer 235 will switch to being called a “sacrificial layer 235” since the material remains the same but the role changes.

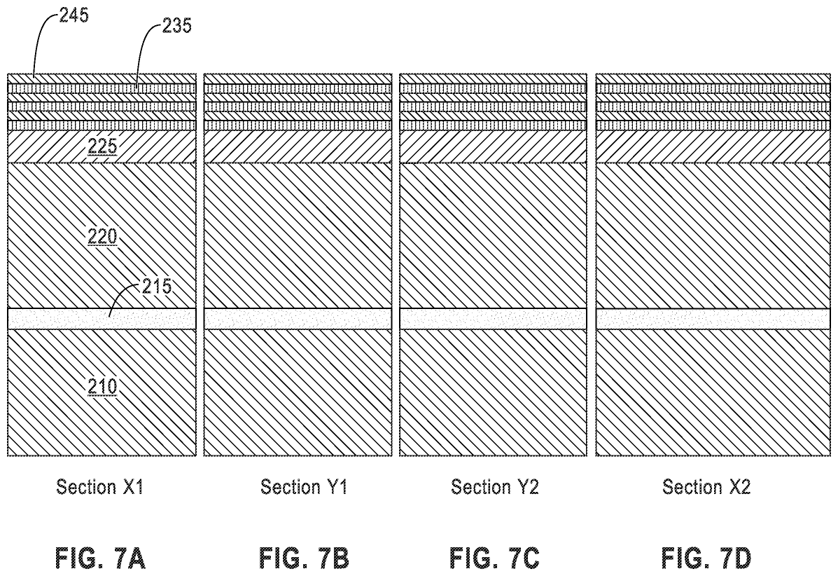

FIGS. 7A-7D to 10A-10D show views along the four different axes defined in FIGS. 1A and 1B. FIGS. 7A-7D show formation of a stack of nanosheets on top of the dielectric layer 225. The nanosheets may include alternating layers of sacrificial layers 235 and semiconductor layers 245. Further down the process, the semiconductor layers 245 will be used as semiconductor channels in an active device and will be referred to as “semiconductor channels 245” at that time.

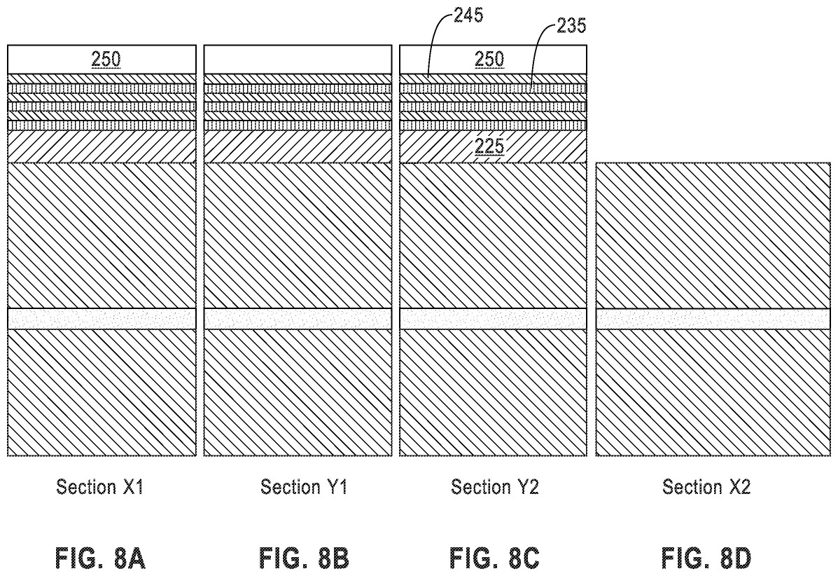

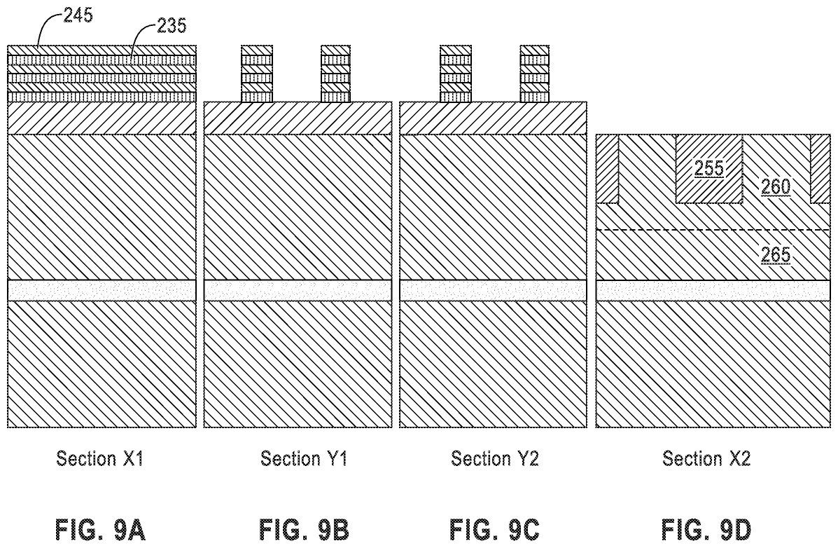

FIGS. 8A-8D show application of a hard mask 250 over the nanosheets in the logic region. The nanosheet material and the dielectric layer 225 in the passive device region may be left exposed by the hard mask 250 resulting in the removal of the dielectric layer 225, the sacrificial layers 235 and the semiconductor layers 245 in the passive device region as seen in FIG. 8D. FIGS. 9A-9D show a process for patterning active component features in the logic device region and implanting features in the passive device region. As shown in FIGS. 9B and 9C, the stack of nanosheets that remain in the logic device region may be patterned into fin structures. In the passive device region, the substrate 220 may be prepared for diode formation.

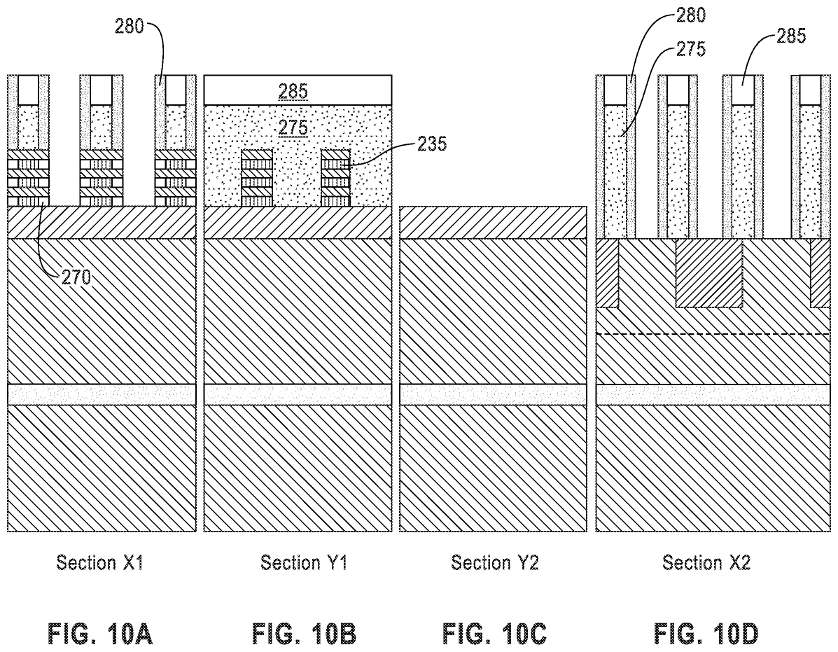

In one embodiment, a twin well formation may be used including an N-well layer 260 over a P-substrate layer 265. Shallow trench isolators 255 may be formed in the N-well layer 260. As will be understood, embodiments may switch the N type and P type material in layers 260 and 265 if desired. The formation in FIGS. 9A-9D show structure after removal of the hard mask 250 of FIGS. 8A-8D. FIGS. 10A-10D show the result of forming a dummy gate 275. Embodiments may include selectively indenting inward, sections of the sacrificial layers 235 (see FIG. 10A) and filling the voids defined by indentation with inner spacer material 270. Some embodiments may form a spacer layer 280 around the dummy gate 275 material as shown in FIGS. 10A and 10D. A hard mask 285 defines where material is removed leaving behind active component support structures (for example, fins).

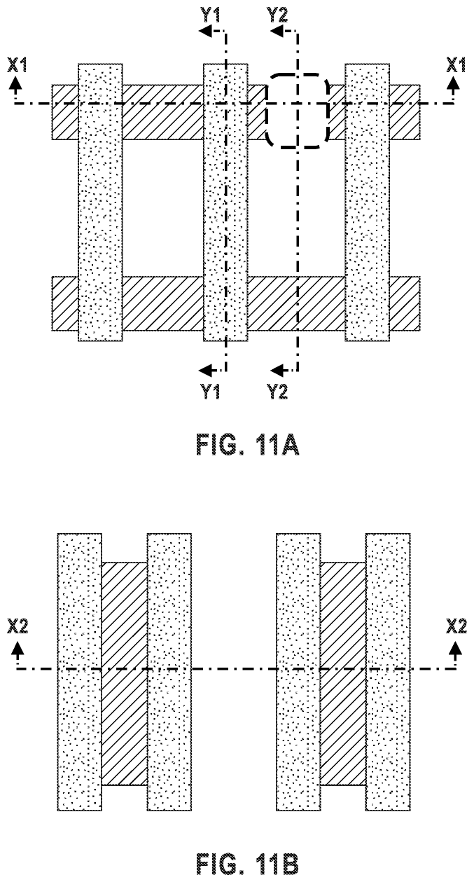

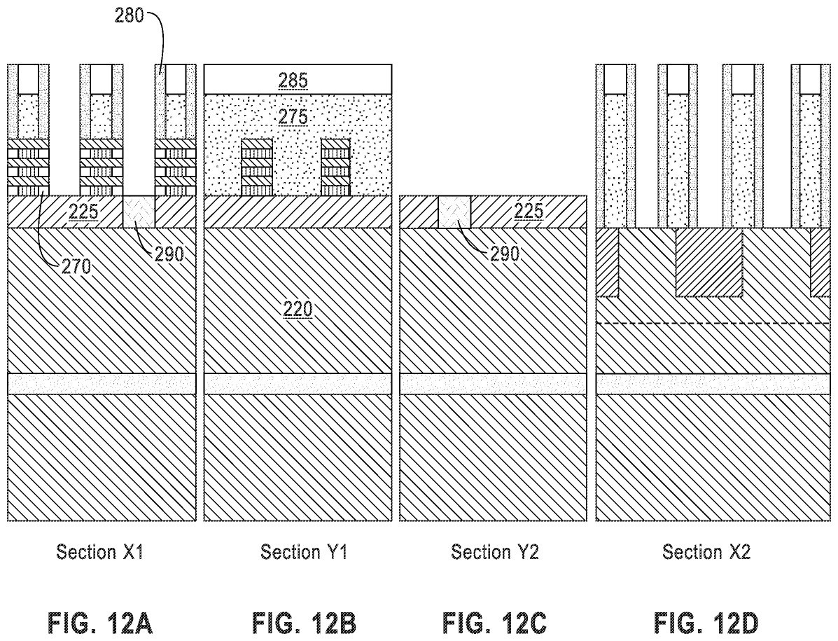

FIGS. 11A and 11B show the legends in FIGS. 1A and 1B modified to highlight an area of the dielectric layer 225 being processed in the logic region in FIGS. 12A-12D. The area is at an intersection of the lines X1 and Y2. In FIGS. 12A-12D, focus is placed on FIGS. 12A and 12C where a sacrificial placeholder feature 290 is formed in the buried oxide layer 225. In some embodiments, the back side surface of the sacrificial placeholder feature 290 is level with the back side surface of the buried oxide layer 225. In some embodiments, the sacrificial placeholder feature 290 remains entirely within the thickness of the buried oxide layer 225.

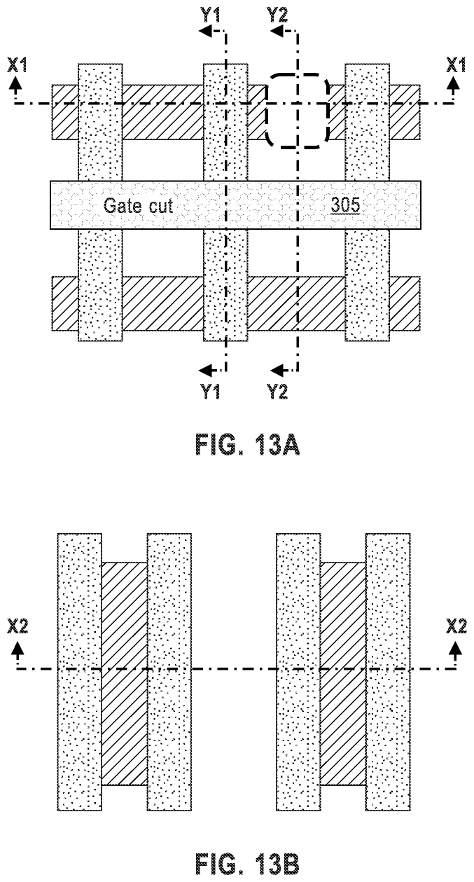

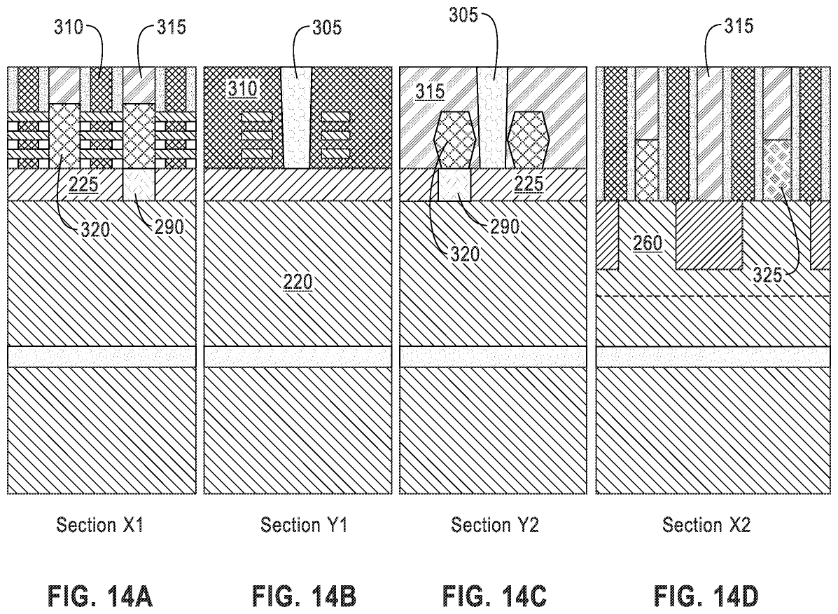

FIGS. 13A and 13B are the same as the legends shown in FIGS. 11A and 11B except that a gate cut region 305 is added in the logic region. Referring now to FIGS. 14A-14D, which should be viewed with concurrent reference to FIGS. 13A and 13B, the process shows formation of active components in the logic region and passive devices in the passive region. FIGS. 14A and 14C show the formation of a source and drain region 320 from epitaxial growth in the logic device region. Part of the source and drain region 320 may be grown over the sacrificial placeholder feature 290. In some embodiments, the source/drain region 320 may be a P-type material. An N-type source/drain region 325 can be seen in the passive device region (FIG. 14D). FIGS. 14A-14D also show replacement of the dummy gate 275 material and sacrificial layers 235 that were still present in FIGS. 12A-12D, with gate material 310 (for example, a High K metal gate material). As shown in FIG. 14B, a gate cut region 305 may be formed in the gate material 310. Some embodiments may include deposition of an interlayer dielectric 315 on and around the source and drain regions 325 and the sacrificial placeholder feature 290. Some embodiments may apply a planarization process to the top surface of the structure shown.

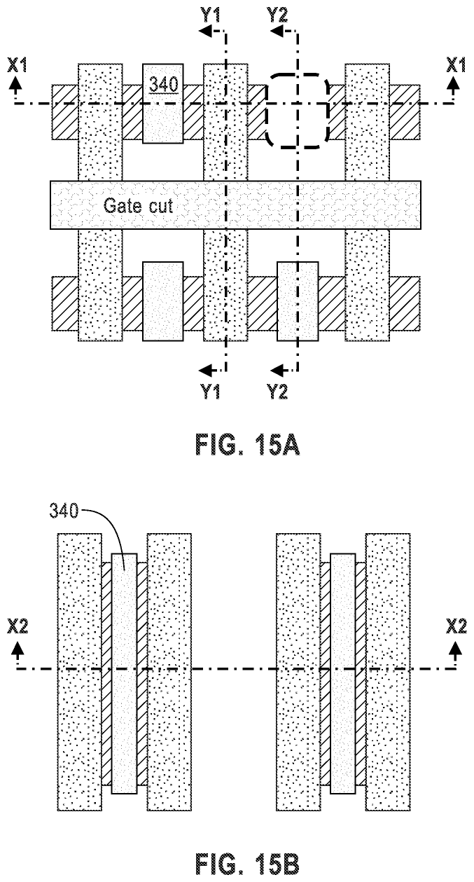

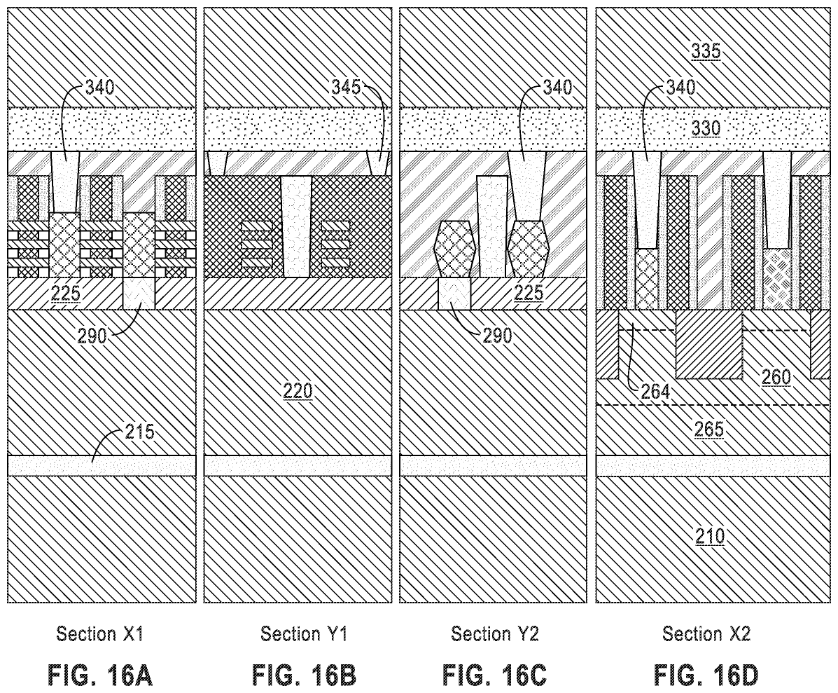

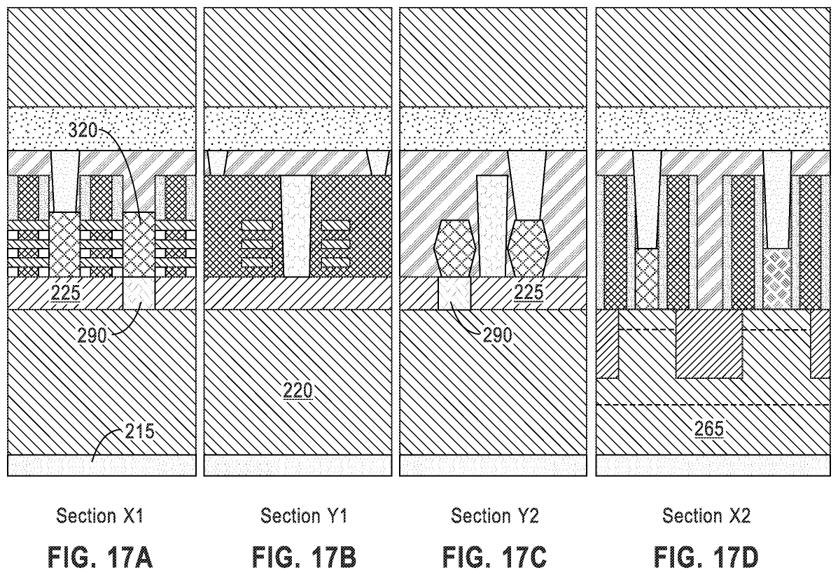

FIGS. 15A and 15B are the same as the legends shown in FIGS. 13A and 13B except that metal contacts 340 can be seen from above as added by the process shown in FIGS. 16A-16D. In FIGS. 16A-16D, additional interlayer dielectric 315 may be deposited and planarized, holes may be formed in the interlayer dielectric 315 to receive formation of metal contacts 340 and 345. As shown in FIGS. 16A, 16C, and 16D, metal contacts 340 connect the top side to the source and drain regions 320 and 325. The metal contact 345 connects the top side to the gate material 310 as shown in FIG. 16C. FIGS. 16A-16D also show formation of a back end of line layer 330 on top of the interlayer dielectric 315 and metal contacts 340 and 345. A carrier wafer 335 may be bonded to the exposed side of the back end of line layer 330. In the following, FIGS. 17A-17D to FIGS. 24A-24D should continue to reference the legends shown in FIGS. 15A and 15B.

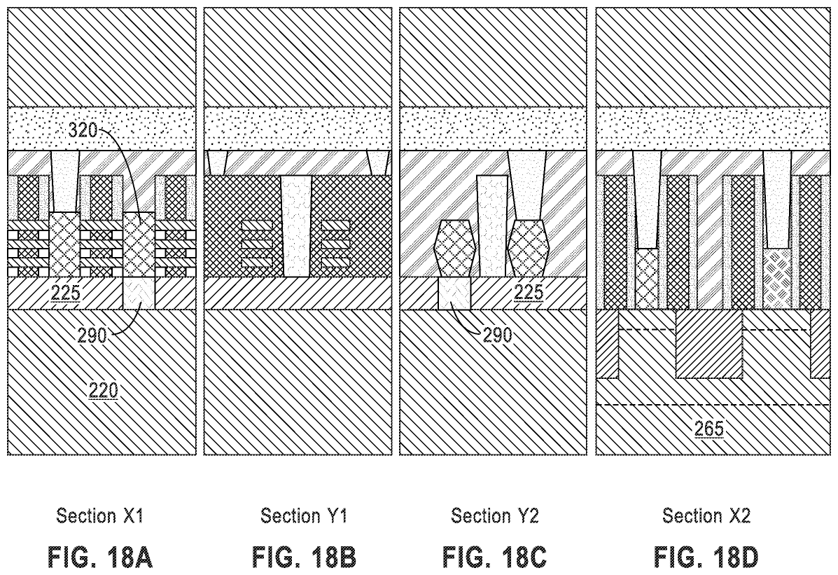

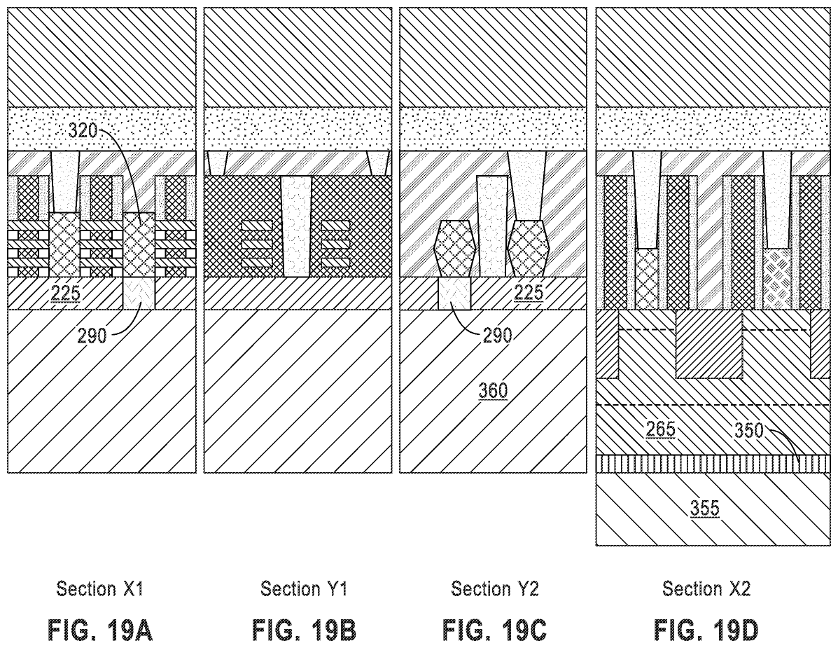

FIGS. 17A-17D show removal of the substrate layer 210 after a wafer flip. It should be understood that the orientation of the structure is maintained consistent with the result shown in FIGS. 16A-16D for sake of illustration, but in practice, the processes applied may be occurring with the wafer flipped over, affecting the layers from the backside of the device. FIGS. 18A-18D show removal of the etch stop layer 215 after being exposed by the removal of substrate layer 210 in FIGS. 17A-17D. The result exposes the substrate layer 220 in the logic device region and the P-substrate layer 265 in the passive device region. FIGS. 19A-19D show removal of the substrate layer 220 in the logic device region, exposing the buried oxide layer 225 and sacrificial placeholder feature 290. Although exposed, it should be appreciated that the sacrificial placeholder feature 290 remains mostly protected being within the buried oxide layer 225 during the removal of the substrate layer 220. In addition, the buried oxide layer 225 is less prone to forming microscopic channels during the silicon removal process. As such, the active components on the other side of the buried oxide layer 225 are protected from attack by the chemistry used during substrate removal.

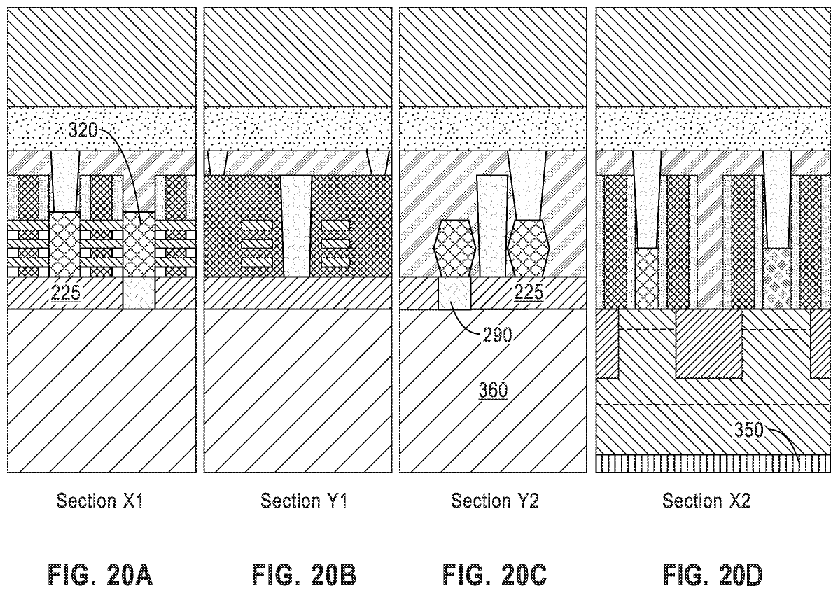

In the passive device region, a hard mask 350 may be applied protecting the P-substrate layer 265 during removal of the substrate layer 220. Embodiments may deposit an OPL 355 over the hard mask 350. FIGS. 20A-20D show deposition of an interlayer dielectric 360 on top of (from the backside direction) the dielectric layer 225 and sacrificial placeholder feature 290. In some embodiments, the OPL 355 may be removed. Some embodiments may include planarization of the interlayer dielectric 360 and some of the hard mask 350. The level of the interlayer dielectric 360 may be short of the level for the hard mask 350.

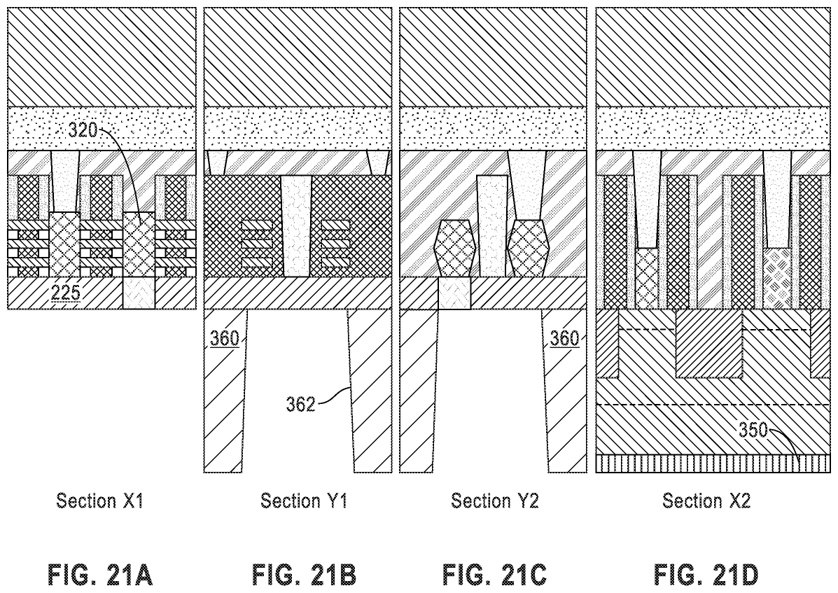

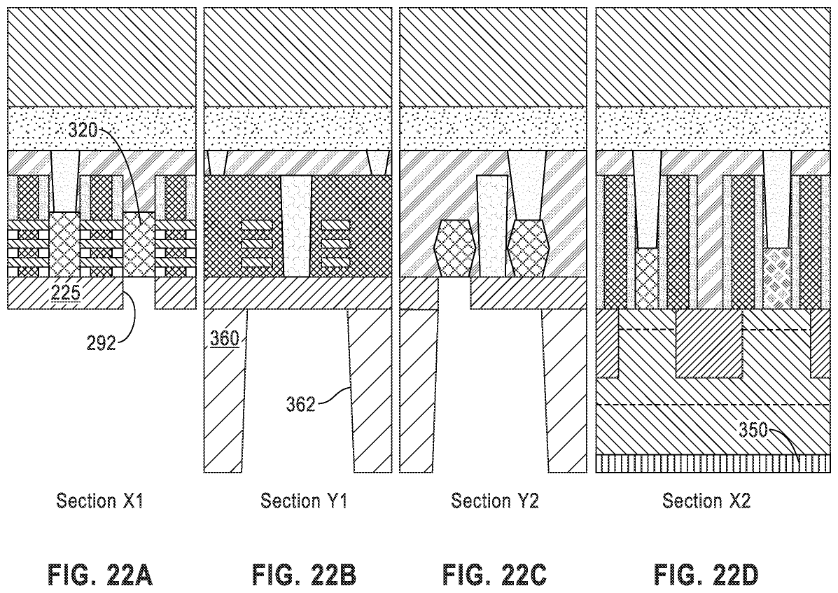

FIGS. 21A-21D show patterning of the interlayer dielectric 360 from the backside for power rail formation. Patterning of the interlayer dielectric 360 exposes portions of the dielectric layer 225 and exposes the sacrificial placeholder feature 290. FIGS. 22A-22D show removal of the sacrificial placeholder feature 290 from the buried oxide layer 225. Removal of the sacrificial placeholder feature 290 forms a cavity 292 and exposes the source and drain region 320 to access from the backside. Removal of the interlayer dielectric 360 defines power rail walls 362 in the voids that were created.

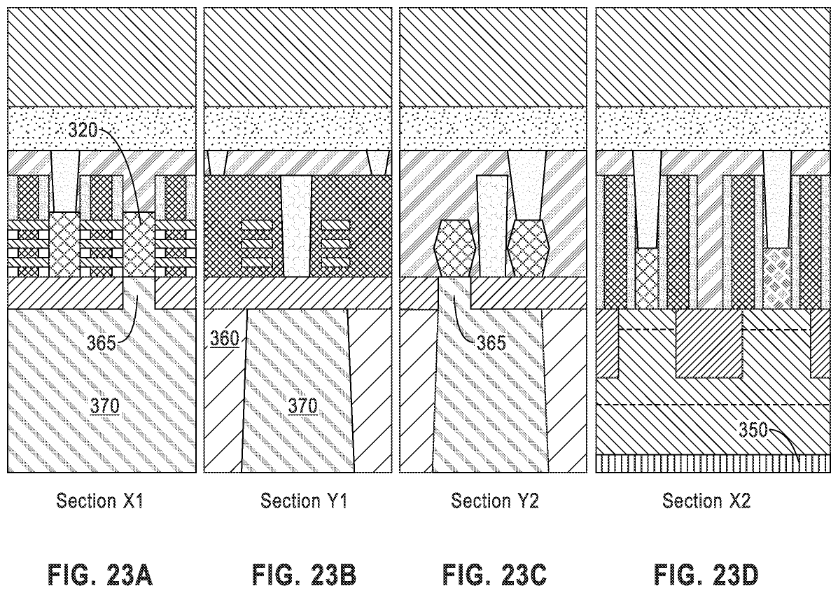

FIGS. 23A-23D show formation of a buried metal contact 365 in the cavity 292 and formation of a metal power rail 370 using for example, a dual damascene process. The metal power rail 370 may be formed in the voids of patterning in the interlayer dielectric 360. The metal power rail 370 may be in direct connection with the buried metal contact 365 providing backside electrical access to the source and drain region 320. In some embodiments, the buried metal contact 365 and power rail 370 may be a single metal element. FIGS. 24A-24D show formation of a backside interconnect layer 375 on top of the metal power rail 370 and interlayer dielectric 360 in the logic device region and on top of the layer 350 in the passive device region. In one embodiment, the structure in the final result may include a transistor in the logic device region and a diode in the passive device region.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate;
an electronic components layer supported by the substrate, including a plurality of active component structures;
a power rail positioned on a back side of the electronic components layer;
a buried oxide layer positioned between the electronic components layer and the power rail; and
a back side metal contact buried in the buried oxide layer, wherein the back side metal contact bridges one of the active components in the electronic components layer to the power rail.

2. The semiconductor device of claim 1, further comprising a plurality of nanosheet stacks of semiconductor channels in the electronic components layer.

3. The semiconductor device of claim 1, wherein the plurality of active components includes one or more transistor structures.

4. The semiconductor device of claim 1, further comprising a back side interconnect layer coupled to a back side of the power rail.

5. The semiconductor device of claim 1, further comprising a back end of line layer coupled to a front side of the electronic components layer.

6. The semiconductor device of claim 5, further comprising one or more passive devices supported by the substrate and connected to the back end of line layer.

7. A semiconductor device, comprising:
a substrate;
a transistor supported by the substrate, including:
a source and drain region;
a gate region; and
one or more semiconductor channels connected between the source and drain region;
a buried oxide layer positioned on a back side of the transistor;
a buried metal contact positioned in the buried oxide layer, wherein the buried metal contact is in electrical contact with the source and drain region of the transistor; and
a power rail positioned on a back side of the buried oxide layer and in electrical contact with the buried metal contact.

8. The semiconductor device of claim 7, further comprising a passive device supported by the substrate.

9. The semiconductor device of claim 8, further comprising a back end of line layer coupled to a front side of the transistor.

10. The semiconductor device of claim 7, further comprising a back side interconnect layer coupled to a back side of the power rail.

11. The semiconductor device of claim 7, wherein a thickness of the buried oxide layer is between 30 nm to 60 nm.

12. The semiconductor device of claim 7, further comprising a plurality of stacked nanosheet semiconductor channels in the transistor.

13. The semiconductor device of claim 7, further comprising a gate all around structure in the transistor.

14. A method of manufacturing a semiconductor device, comprising:
forming a buried oxide layer on top of a substrate;
forming a stack of nanosheets on a front side of the buried oxide layer, wherein the stack of nanosheets includes alternating layers of sacrificial layers and semiconductor channel layers;
patterning active component support structures from the stack of nanosheets;
forming a back side contact placeholder feature buried in the buried oxide layer;
forming, on the front side of the buried oxide layer and on top of the back side contact placeholder feature, active components using the active component support structures;
removing the substrate from a back side of the buried oxide layer;
removing the back side contact placeholder feature from the buried oxide layer;
depositing, from the back side of the buried oxide layer, a metal contact in a cavity of the buried oxide layer, defined by the removal of the back side contact placeholder feature; and
forming a power rail on the back side of the buried oxide layer, in contact with the metal contact.

15. The method of claim 14, further comprising forming the buried oxide layer in a thickness ranging from 30 nm to 60 nm.

16. The method of claim 14, further comprising forming an active component layer on top of the buried oxide layer, wherein the metal contact is coupled to an active component in the active component layer.

17. The method of claim 14, further comprising forming a passive component proximate the active component layer.

18. The method of claim 17, further comprising forming a back end of line layer coupled to the active component layer and to the passive component.

19. The method of claim 16, further comprising forming a stacked nanosheet transistor in the active component layer.

20. The method of claim 14, further comprising forming a back side interconnect layer coupled to a back side of the power rail.
